(19) United States
(12) Patent Application Publication
(10) Pub. No.: US 2007/0231972 A1
(43) Pub. Date: Oct. 4, 2007

(54) Manufacture of programmable crossbar signal processor

(76) Inventor: Blaise Laurent Mouttet, Arlington, VA (US)

Correspondence Address: Blaise Mouttet, #110-364, 4201 Wilson Blvd., Arlington, VA, 22203, US

(21) Appl. No.: 11/798,647

(22) Filed: May 16, 2007

Related U.S. Application Data
(63) Continuation-in-part of application No. 11/395,237, filed on Apr. 3, 2006.

(51) Int. Cl. H01L 21/768; H01L 21/77

(52) U.S. Cl. 438/131; 438/455; 257/E21.495; 257/E21.575; 257/E21.598

(57) ABSTRACT

A process including a first step of providing a semiconductor wafer doped of a first conductivity type on a first side and doped of a second conductivity type, opposite to the first conductivity type on the second side, a second step of forming a first array of parallel wires having electrical conductivity on the first side, a third step of forming a second array of parallel wires having electrical conductivity on the second side, a fourth step of forming an insulating layer on the first side after the first array of parallel wires is formed, and a fifth step of forming a programmable impedance layer on the second side after the second array of wires is formed.

### CROSS-REFERENCE TO RELATED APPLICATIONS

This application is a continuation-in-part of the co-pending U.S. patent application Ser. No. 11/395,237, filed Apr. 3, 2006, which is incorporated by reference in its entirety.

This application is related to the following co-pending patent application, which is incorporated by reference in its entirety:

U.S. application Ser. No. 11/395,232, entitled “Crossbar Arithmetic Processor,” filed Apr. 3, 2006.

### FIELD OF THE INVENTION

The present invention pertains to the manufacture of a crossbar processing system as used in a variety of applications including signal processing systems, pattern recognition systems, and arithmetic processing systems.

### BACKGROUND OF THE INVENTION

As discussed in U.S. patent applications Ser. Nos. 11/395,237 and 11/395,232 the use of impedance programmable materials in a crossbar wiring architecture can enable a variety of applications in signal processing and arithmetic processing systems. The present application teaches one possible manufacturing process for a crossbar array used in these and other applications.

### SUMMARY OF THE INVENTION

A process is disclosed including a first step of providing a semiconductor wafer doped of a first conductivity type on a first side and doped of a second conductivity type, opposite to the first conductivity type on the second side, a second step of forming a first array of parallel wires having electrical conductivity on the first side, a third step of forming a second array of parallel wires having electrical conductivity on the second side, a fourth step of forming an insulating layer on the first side after the first array of parallel wires is formed, and a fifth step of forming a programmable impedance layer on the second side after the second array of wires is formed.

### BRIEF DESCRIPTION OF THE DRAWINGS

FIG. 1a illustrates a top view of basic circuit configuration for one embodiment of a crossbar signal processing unit.

FIG. 1b illustrates a cross-sectional view of the crossbar array of FIG. 1a.

FIGS. 2a-2d illustrate a fabrication procedure for a crossbar array.

FIG. 3 illustrates the top view of a bonded state of two substrates used in forming a crossbar array.

FIG. 4 illustrates an embodiment of the crossbar array combined with particular signal processing circuitry to create a crossbar signal processor.

FIG. 5 illustrates a crossbar signal processor combined with a crossbar signal selector circuit to form a multiple-input/multiple-output crossbar signal processor configuration.

FIG. 6 illustrates a crossbar signal processor combined with a summing circuit to form a single-input/single-output crossbar signal processor configuration.

### DETAILED DESCRIPTION

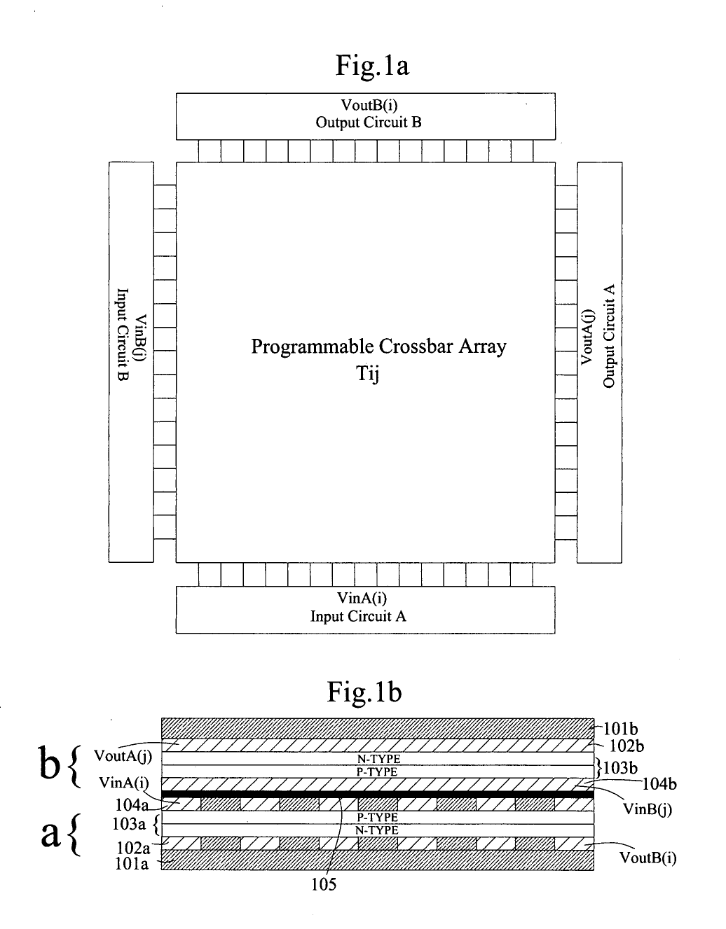

FIG. 1a illustrates a top view of basic circuit configuration for one embodiment of a crossbar signal processing unit which is further described in parent U.S. patent application Ser. No. 11/395,237 and which includes input circuit A, input circuit B, output circuit A, and output circuit B providing programming or signal voltages VinA(i), VinB(j) and output connections VoutA(j), VoutB(i).

FIG. 1b illustrates a cross-sectional view of the crossbar array of FIG. 1a. The crossbar array may be formed by sandwiching a programmable impedance material 105 between semiconductor rectification layers a, b. The programmable material 105 may take the form of any organic conducting polymer, nanocomposite film, or molecular film known to the art in which at least the electrical resistance may be modified. The two semiconductor rectification layers a,b have complementary structure including insulating substrates 101a/101b, conductive wiring 102a/102b, which are configured as cathode electrodes, pn semiconductor junctions 103a/103b, and conductive wiring 104a/104b, which are configured as anode electrodes.

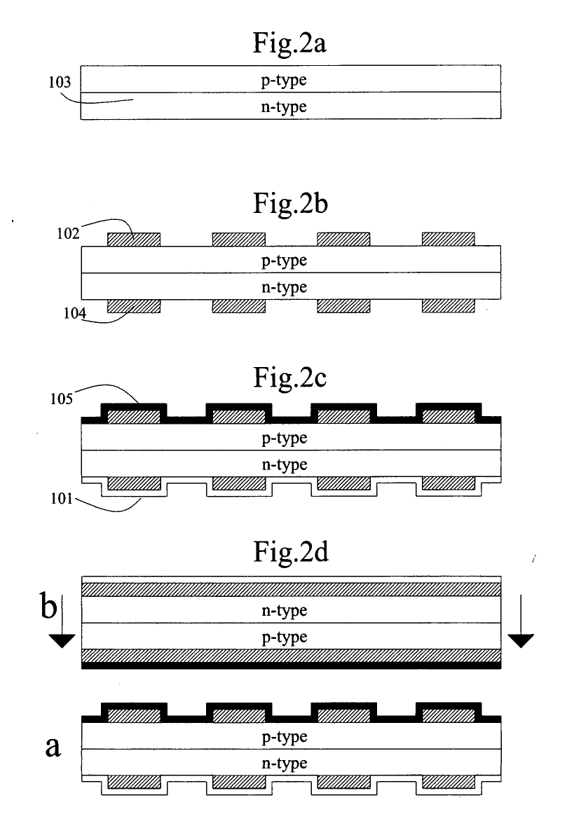

FIGS. 2a-2d illustrate a fabrication procedure for a crossbar array according to the present invention.

In FIG. 2a, a semiconductor wafer such as silicon is initially provided uniformly doped of a first conductivity type (p-doped or n-doped). One side of the wafer is doped of the opposite conductivity type using conventional diffusion or ion implantation techniques so as to form a semiconductor wafer 103 with pn junction rectification characteristics.

In FIG. 2b, two-sided processing is used to form conductive wiring patterns 102, 104 on either side of semiconductor wafer 103. The wiring may be patterned using optical lithography, e-beam lithography, imprint lithography, or any other known lithography process. Conductive inks can potentially be used to form the wiring in which case transfer, offset, or inkjet printing techniques may be used to pattern the wires. The material of the wiring may be any metallic or other electrically conductive material including Ag, Al, Au, Cr, Cu, Ni, Pt, Ti, W, or any other known electrical conductive material known to the semiconductor industry. In order to avoid creating unwanted pn junctions different materials or processes may be chosen in forming the wiring 102 in contact with the p-doped side of wafer 103 and the wiring 104 in contact with the n-doped side of wafer 103.

In FIG. 2c, insulating material film 101 and programmable impedance material film 105 are coated onto opposite sides of the wafer. The insulating film may be silicon dioxide, silicon nitride, polyimide or any other known or useful insulating thin film deposited using CVD or other coating techniques known to the semiconductor processing art. The programmable impedance material film 105 may be formed as one of a variety of organic conducting polymer, nanocomposite film, or molecular film known to the art in which at least the electrical resistance may be modified examples of which are discussed in patents U.S. Pat. No. 5,272,359, U.S. Pat. No. 6,128,214, U.S. Pat. No. 6,531,371, U.S. Pat. No. 6,693,821, U.S. Pat. No. 6,746,971, U.S. Pat. No. 6,867,996, U.S. Pat. No. 6,960,783, and U.S. Pat. No. 6,995,649, each of which is incorporated by reference in their entirety.

The steps of FIG. 2a-2c are illustrated in the case that the processing is done on both sides of the substrate simultaneously. However, the steps of FIG. 2a-2c may be processed for one side prior to performing the steps of FIG. 2a-2c for the second side. Preferably, the side including insulating film 101 is completed first. Once the processing of FIG. 2a-2c is finished the wafer 103 may be diced into two segments a,b, As shown in FIG. 2d, segment b is oriented in a perpendicular (or at least non-parallel) orientation to segment a and the two segments are bonded together. A processing step may then be performed to bond or fuse the two wafer segments. Optionally, the two segments may be held fixed together by a pressure inducing clip or other device.

In an alternative embodiment, a second semiconductor wafer may be processed according to steps 2a-2c and used in the bonding/fusing of FIG. 2d. Dicing and packaging steps, as known in semiconductor processing, may be further used to complete a manufacturing process and form several crossbar circuits from the bonded wafers.

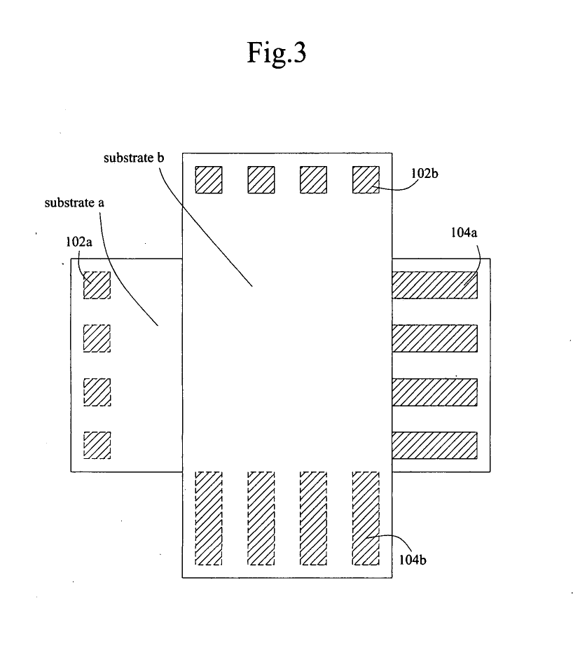

FIG. 3 illustrates the top view of a bonded state of two substrates a, b used in forming a crossbar array. On the top side of substrate b, wiring 102b is exposed through the insulating layer 101b to form contacts for external leads to connect to output circuit A of FIG. 1. On the opposite side of substrate b, the extension of wiring 104b (shown in dashed outline) is used to form contacts for external leads to connect to input circuit B of FIG. 1. On the top side of substrate a, the extension of wiring 104a is used to form contacts for external leads to connect to input circuit A of FIG. 1. On the opposite side of substrate a, wiring 102a (shown in dashed outline) is exposed through the insulating layer 101a to form contacts for external leads to connect to output circuit B of FIG. 1.

In an alternative embodiment, input circuit A, output circuit A, input circuit B, and output circuit B may be integrated on the respective sides of the substrates of the wiring to which the circuits connect. The input and output circuitry may take a variety of forms such as that discloses in co-pending patent applications Ser. Nos. 11/395,237 or 11/395,232.

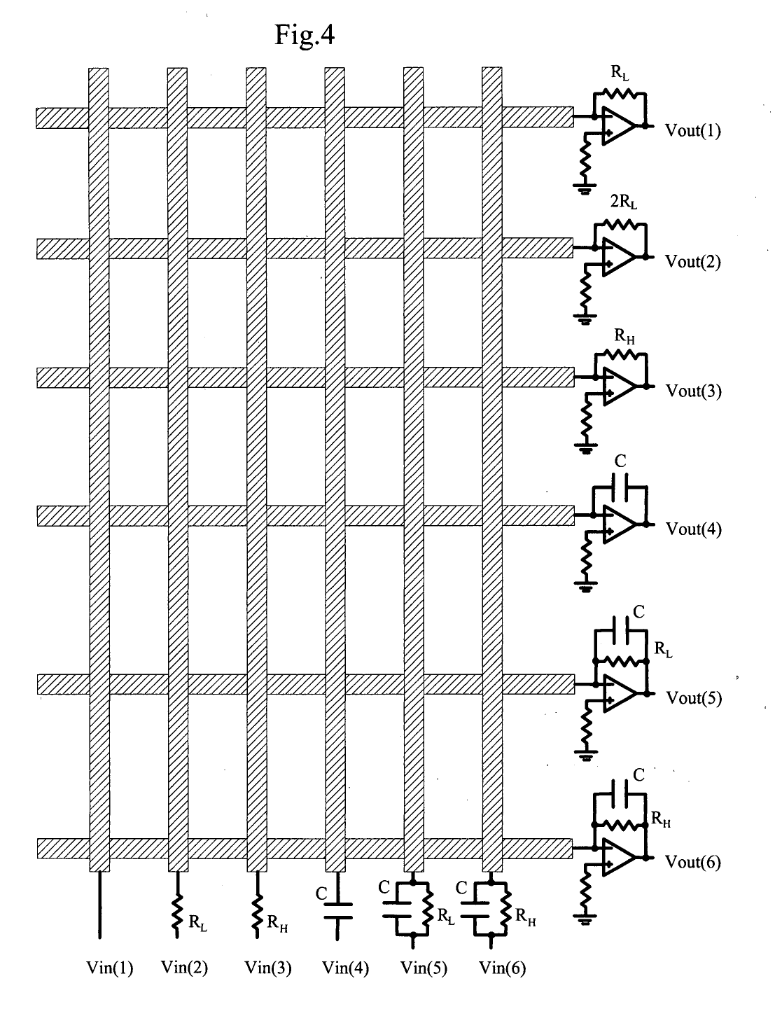

FIG. 4 illustrates one embodiment of signal processing input/output circuitry associated with the crossbar array to create one possible crossbar signal processor. Distinct processing elements are used associated with each input and output wire. Input signal Vin(1) is placed in direct electrical connection to the first vertical wire. Input signal Vin(2) is connected to the second vertical wire via a resistance value equal to the low resistance state (R_{L}) of the programmable impedance material 105. Input signal Vin(3) is connected to the third vertical wire via a resistance value equal to the high resistance state (R_{H}) of the programmable impedance material 105. Input signal Vin(4) is connected to the fourth vertical wire via a capacitance value C. Input signal Vin(5) is connected to the fifth vertical wire via a parallel combination of R_{L} and C. Input signal Vin(6) is connected to the sixth vertical wire via a parallel combination of R_{H} and C. The horizontal output wires are connected to the outputs via inverting op-amps with respective feedback impedances of R_{L}, 2R_{L}, R_{H}, X_{C}, R_{L}∥X_{C}, R_{H}∥X_{C} (X_{C} is the reactance of the capacitor) to produce outputs Vout(1)-Vout(6). By selectively programming each of the crosspoints of the crossbar array to the high or low resistance state 2³⁶ (approx. 64 billion) possible circuit states exist. By programming intermediate resistance states in the crossbar between R_{L} and R_{H} the circuit configurations can be further tuned. Depending on the desired application different values of the resistances and capacitance may be used, different circuit elements may be used for the input and feedback impedances, and larger or smaller crossbar configurations may be formed. Such modifications would be an obvious matter of optimization to a person of ordinary skill in the art. Reprogrammable circuit architectures (i.e. morphware) that can be adapted to a variety of states (e.g. conversion between high-pass/low-pass/band-pass circuit functions, conversion between integrator/differentiator functions, waveform modulation conversion, etc.) may be formed using the crossbar signal processor of the present invention as further described in the parent U.S. patent application Ser. No. 11/395,237. Furthermore given the large number of circuit states that can be formed in large programmable crossbar arrangements, techniques of genetic algorithms may be applied to evolve and optimize circuit constructions to solve particular problems which can be particularly advantageous to machine learning and artificial intelligence.

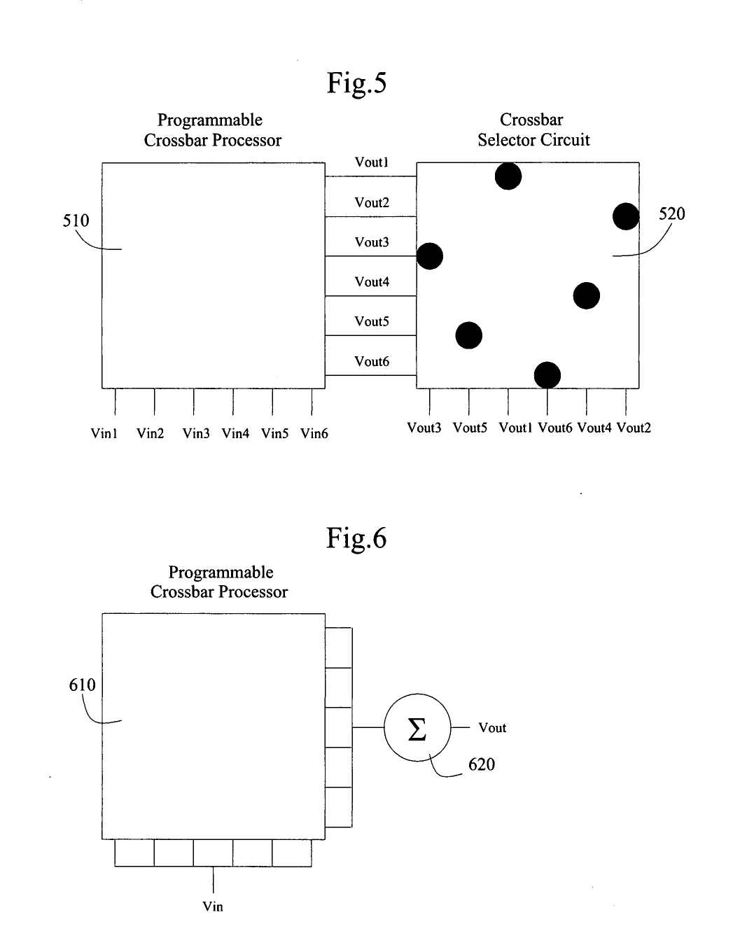

FIG. 5 illustrates a crossbar signal processor combined with a crossbar signal selector circuit to form a multiple-input/multiple-output crossbar signal processor configuration. The crossbar configuration of FIG. 4 may be used for circuit 510 and the selector circuit 520 may be formed using a crossbar circuit with all of the input impedances to the input wires set to a resistance value equal to the low resistance state (R_{L}) of the programmable impedance material 105 and all of the feedback impedances of the op-amps set to a resistance value equal to twice the low resistance state (2R_{L}) of the programmable impedance material 105. The magnitude of the transfer function characterizing the crossbar in this case would be Tij=2R_{L}/(R_{L}+Rij) where Rij is the resistance value at particular crosspoints of the crossbar. For Rij=R_{H} and R_{H}>>R_{L}, Tij is approximately zero and for Rij=R_{L}, Tij=1. The circuit 520 illustrates a particular pattern of programmed low resistance states by dark circles and the resultant outputs produced. The multiple-input/multiple-output circuit configuration may optionally be cascaded with additional multiple-input/multiple-output crossbar signal processors to achieve the advantage of a larger number of possible circuit configurations.

FIG. 6 illustrates an embodiment of a crossbar signal processor 610 combined with a summing circuit 620 to form a single-input/single-output crossbar signal processor configuration. Various combinations of the embodiments of FIG. 5 and FIG. 6 may be provided to produce single-input/multiple-output or multiple-input/single-output crossbar signal processors.

Various modifications may be made to the present invention. For example, the orientation of p-doped side and n-doped side of layers 103a/103b of FIG. 1b may be reversed provided that the anode/cathode arrangement of the input and output circuits are also reversed. In any of the various embodiments in this and the parent patent application, the input signals may be received from one of a variety of sources including a computer processor, a sensor such as an environmental sensor (temperature, humidity, vibration, pressure, chemical), an optical or image sensor, an audio sensor, a motion sensor, user input, a signal from a biological system such as the human nervous system, or any other known sensor input. The output signals may be transmitted to drive various devices such as motors, visual or audio indicators, imaging displays, sound producing devices, or any other known electronic or electrically controlled output mechanism. Since signal paths and functions can be programmed via crossbar signal processors they are applicable to biological control systems that can create dynamic mappings between neural impulses and muscle control. It would be obvious for a person or ordinary skill in the art to apply the teachings of the present or related inventions involving reconfigurable crossbar electronics to a variety of processing systems including, but not limited to, control, communication, arithmetic processing, and pattern recognition in order to provide the advantages of adaptability and reconfigurability provided by the use of programmable impedance material in crossbar configurations.

The invention is only limited by the following claims.

I claim:

1. A process comprising:
providing a semiconductor wafer doped of a first conductivity type on a first side and doped of a second conductivity type, opposite to the first conductivity type, on the second side;
forming a first array of parallel wires having electrical conductivity on the first side;
forming a second array of parallel wires having electrical conductivity on the second side;
forming an insulating layer on the first side after the first array of parallel wires is formed; and
forming a programmable impedance layer on the second side after the second array of wires is formed.

2. The process of claim 1 further comprising:
dicing the semiconductor wafer into two segments and orienting the two segments relative to one another such that the programmable impedance layer of each segment are in contact and then bonding the two segments.

3. The process of claim 1 further comprising:
providing a second semiconductor wafer of symmetrical structure to the first semiconductor wafer and orienting the two wafers relative to one another such that the wafers are in contact and then bonding the two wafers.

4. The process of claim 1 wherein the first side of the wafer is doped to be n-type and the second side of the wafer is doped to be p-type.

5. The process of claim 1 including forming input circuitry on the second side of the semiconductor wafer electrically connected to the second array of parallel wires and forming output circuitry of the first side of the semiconductor wafer electrically connected to the first array of parallel wires.

6. The process of claim 1 wherein the first array of parallel wires are oriented in parallel to the second array of parallel wires.

7. The process of claim 1 wherein the programmable impedance layer is an organic conducting polymer having an electrical resistance that may be modified.

8. The process of claim 1 wherein the programmable impedance layer is a nanocomposite film having an electrical resistance that may be modified.

9. The process of claim 1 wherein the programmable impedance layer is a molecular film having an electrical resistance that may be modified.

10. The process of claim 1 wherein the first array of parallel wires and insulating layer are formed on the first side prior to the second array of parallel wires and the programmable impedance material being formed on the second side.
